(19) United States
(12) Patent Application Publication
(10) Pub. No.: US 2026/0223567 A1
(43) Pub. Date: Jul. 30, 2026

(54) LIGHT EMITTING DISPLAY DEVICE

(71) Applicant: LG Display Co., Ltd., Seoul (KR)

(72) Inventors: Dong Myung LEE, Paju-si (KR); Suk Hyun WON, Paju-si (KR)

(73) Assignee: LG Display Co., Ltd., Seoul (KR)

(21) Appl. No.: 19/447,287

(22) Filed: Jan. 13, 2026

(30) Foreign Application Priority Data
Jan. 24, 2025 (KR) 10-2025-0011976

(51) Int. Cl. H10K 59/80; H10K 50/19; H10K 59/122; H10K 59/124; H10K 59/38; H10K 59/88

(52) U.S. Cl. CPC H10K 59/80515; H10K 50/19; H10K 59/122; H10K 59/124; H10K 59/38; H10K 59/88

(57) ABSTRACT

Disclosed is a light emitting display device. The light emitting display device includes a substrate comprising a plurality of sub-pixels, each comprising an emission portion and a non-emission portion, a pixel circuit on the substrate, a planarization layer covering the pixel circuit, a light emitting device comprising a first electrode on the planarization layer and provided at an entire area of the emission portion and at a part of the non-emission portion at each of the plurality of sub-pixels, a bank on the planarization layer and exposing the emission portion of the first electrode and an air pocket below the bank and disposed at an upper surface of the planarization layer.

This application claims the benefit of Korean Patent Application No. 10-2025-0011976, filed on Jan. 24, 2025, which is hereby incorporated by reference as if fully set forth herein.

### BACKGROUND

### Field of the Disclosure

The present disclosure relates to a light emitting display device that exhibits improved optical efficiency.

### Discussion of the Related Art

As the information society advances, the demand for display devices capable of displaying images is increasing in various forms.

A light emitting display device, in which pixels are constituted by light emitting devices, does not require a separate light source unit, which makes it advantageous for slim or flexible form factors. In addition, such a light emitting display device provides excellent color purity.

As an example, a light emitting device includes two different electrodes and an emission layer disposed therebetween.

Since the light emitting display device utilizes light emitted from the light emitting device itself without a separate light source unit, various studies have been conducted to utilize light emitted from the light emitting device for display purposes with minimal loss.

### SUMMARY

Accordingly, the present disclosure is directed to a light emitting display device that substantially obviates one or more problems due to limitations and disadvantages of the related art.

An aspect of the present disclosure is to provide a light emitting display device capable of enhancing light extraction efficiency by reducing internal reflection or absorption of light emitted from a light emitting device.

Another aspect of the present disclosure is to provide a light emitting display device capable of increasing the light extraction rate through a substrate by reducing or preventing the light emitted from the light emitting device from being directed toward a light-shielding material in the substrate.

Still another aspect of the present disclosure is to provide a light emitting display device capable of preventing or suppressing light emitted from a specific sub-pixel from causing light leakage into adjacent sub-pixels.

A further aspect of the present disclosure is to provide a light emitting display device capable of improving electro-optical characteristics.

The aspects to be accomplished by the present disclosure are not limited to the above-mentioned aspects, and other aspects not mentioned herein can be clearly understood by those skilled in the art from the following description.

Additional advantages, aspects, and features of the present disclosure will be set forth in part in the description which follows and in part will become apparent to those having ordinary skill in the art upon examination of the following or may be learned from practice of the present disclosure. The aspects and other advantages of the disclosure may be realized and attained by the structure particularly pointed out in the written description and claims hereof as well as the appended drawings.

To achieve these aspects and other advantages and in accordance with the purpose of the present disclosure, as embodied and broadly described herein, a light emitting display device according to an example embodiment of the present disclosure includes a substrate comprising a plurality of sub-pixels, each comprising an emission portion and a non-emission portion, a pixel circuit on the substrate, a planarization layer covering the pixel circuit, a light emitting device comprising a first electrode on the planarization layer and provided at an entire area of the emission portion and at a part of the non-emission portion at each of the plurality of sub-pixels, a bank on the planarization layer and exposing the emission portion of the first electrode and an air pocket below the bank and disposed at an upper surface of the planarization layer.

In another aspect, a light emitting display device according to another example embodiment of the present disclosure includes a substrate comprising a red emission portion, a green emission portion, a blue emission portion, and a white emission portion spaced apart from each other, a pixel circuit on the substrate, a planarization layer covering the pixel circuit, a light emitting device comprising first electrodes respectively at the red emission portion, the green emission portion, the blue emission portion, and the white emission portion on the planarization layer, the first electrodes being spaced apart from each other, a bank on the planarization layer and exposing the red emission portion, the green emission portion, the blue emission portion, and the white emission portion of the first electrodes and an air pocket between the bank and the planarization layer, the air pocket overlapping the bank.

It is to be understood that both the foregoing general description and the following detailed description of the present disclosure are by way of example and explanatory and are intended to provide further explanation of the disclosure as claimed.

### BRIEF DESCRIPTION OF THE DRAWINGS

The accompanying drawings, which are included to provide a further understanding of the present disclosure and are incorporated in and constitute a part of this application, illustrate example embodiment(s) of the present disclosure and together with the description serve to explain principles of the disclosure. In the drawings:

FIG. 1 is a block diagram schematically showing a light emitting display device according to an example embodiment of the present disclosure;

FIG. 2 is a plan view of the light emitting display device according to an example embodiment of the present disclosure;

FIG. 3 is a cross-sectional view taken along line I-I′ in FIG. 2;

FIG. 4 is an enlarged view of region K in FIG. 3;

FIG. 5 is a cross-sectional view showing an example of a light emitting device included in the light emitting display device according to an example embodiment of the present disclosure;

FIG. 6 is a circuit diagram of a sub-pixel according to an example embodiment of the present disclosure;

FIG. 7 is an enlarged view of region K in FIG. 3 according to another example embodiment; and

FIG. 8 is a view showing a relationship between the maximum depth of an air pocket and the curvature of the air pocket according to example embodiments of the present disclosure.

### DETAILED DESCRIPTION

Reference will now be made in detail to various embodiments of the disclosure, examples of which are illustrated in the accompanying drawings. Wherever possible, the same reference numbers will be used throughout the drawings to refer to the same or like parts. In the following description of the present disclosure, detailed descriptions of known functions and configurations incorporated herein may be omitted where the same may obscure the subject matter of the disclosure. In addition, the names of elements used in the following description are selected in consideration of clarity of description of the disclosure and may differ from the names of elements of actual products.

The shapes, sizes, ratios, angles, numbers, and the like, which are illustrated in the drawings to describe various example embodiments of the present disclosure, are merely given by way of example. The disclosure is not limited to the illustrations in the drawings.

In the present specification, where terms such as “including,” “having,” “comprising,” and the like are used, one or more components can be added, unless a more specific term, such as “only,” is used. As used herein, the term “and/or” includes a single associated listed item and any and all of the combinations of two or more of the associated listed items.

An expression such as “at least one of” when preceding a list of elements can modify the entire list of elements and not the individual elements of the list. The term “at least one” should be understood as including any and all combinations of one or more of the associated listed items. For example, the meaning of “at least one of a first element, a second element, and a third element” encompasses the combination of all three listed elements, combinations of any two of the three elements, as well as each individual element, the first element, the second element, and the third element.

The terminology used herein is to describe particular aspects and is not intended to limit the present disclosure. As used herein, the terms “a” and “an” used to describe an element in the singular form is intended to include a plurality of elements. An element described in the singular form is intended to include a plurality of elements, and vice versa, unless the context clearly indicates otherwise.

In construing a component or numerical value, the component or the numerical value is to be construed as including an error or tolerance range even where no explicit description of such an error or tolerance range is provided.

In describing the various example embodiments of the present disclosure, where the positional relationship between two elements is described using terms, such as “on”, “above”, “under” and “next to”, at least one intervening element can be present between the two elements, unless a more specific term like “immediate(ly)” or “direct(ly)” or “close(ly) is used. It should be understood that, where an element or layer is referred to as being “connected to” or “coupled to” another element or layer, it can be directly connected to or coupled to the other element or layer, or one or more intervening elements or layers can be present.

In describing the various example embodiments of the present disclosure, where terms such as “after,” “subsequently,” “next,” and “before” are used to describe the temporal relationship between two events, another event can occur therebetween, unless a more limiting term, such as “just,” “immediate(ly),” or “directly” is used.

In describing the various example embodiments of the present disclosure, terms such as “first” and “second” can be used to describe a variety of components. These terms aim to refer the same or similar components separately from one another and do not limit the components. Accordingly, throughout the specification, a “first” component can be the same as a “second” component, and vice versa, within the technical concept of the present disclosure, unless specifically mentioned otherwise.

Features of various embodiments of the present disclosure can be partially or wholly coupled to or combined with each other, and can be variously inter-operated with each other and driven technically as those skilled in the art can sufficiently understand. The embodiments of the present disclosure can be carried out independently from each other or can be carried out together in a co-dependent relationship.

As used herein, the term “doped” layer refers to a layer including a first material and a second material (for example, n-type and p-type materials, or organic and inorganic substances) having physical properties different from the first material. Apart from the differences in properties, the first and second materials can also differ in terms of their amounts in the doped layer. For example, the host material can be a major component while the dopant material can be a minor component. The first material accounts for most of the weight of the doped layer. The second material can be added in an amount less than 30% by weight, based on a total weight of the first material in the doped layer. A “doped” layer can be a layer that is used to distinguish a host material from a dopant material of a certain layer, in consideration of the weight ratio. For example, if all of the materials constituting a certain layer are organic materials, at least one of the materials constituting the layer is n-type and the other is p-type, when the n-type material is present in an amount of less than 30 wt %, or when the p-type material is present in an amount of less than 30 wt %, the layer is considered to be a “doped” layer.

Further, the term “undoped” refers to layers that are not “doped”. For example, a layer can be an “undoped” layer when the layer contains a single material or a mixture including materials having the same properties as each other. For example, if at least one of the materials constituting a certain layer is p-type and none of the materials constituting the layer are n-type, the layer is considered to be an “undoped” layer. For example, if at least one of the materials constituting a layer is an organic material and none of the materials constituting the layer are inorganic materials, the layer is considered to be an “undoped” layer.

In this present disclosure, an electroluminescence (EL) spectrum can be calculated by multiplying (a) a photoluminescence (PL) spectrum, which applies the inherent characteristics of an emissive material such as a dopant material or a host material included in an organic emission layer, by (b) an outcoupling or emittance spectrum curve, which is determined by the structure and optical characteristics of an organic light-emitting element including the thicknesses of organic layers such as, for example, a hole transport layer and an electron transport layer.

Hereinafter, a light emitting display device according to various example embodiments of the present disclosure will be described with reference to the accompanying drawings.

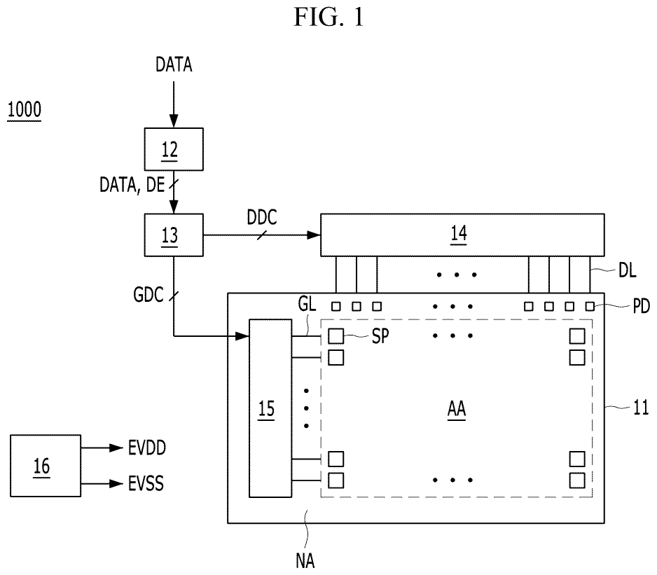

FIG. 1 is a block diagram schematically showing a light emitting display device according to an example embodiment of the present disclosure.

As shown in FIG. 1, a light emitting display device 1000 according to an example embodiment of the present disclosure may include a display panel 11, an image processor 12, a timing controller 13, a data driver 14, a scan driver 15, and a power supply 16.

The display panel 11 may display an image in response to a data signal DATA supplied from the data driver 14, a scan signal supplied from the scan driver 15, and power supplied from the power supply 16.

The display panel 11 may include sub-pixels SP disposed at intersections of a plurality of gate lines GL and a plurality of data lines DL. The structure of the sub-pixels SP may vary depending on the type of light emitting display device 1000.

For example, the sub-pixels SP may be implemented in a top emission type, a bottom emission type, or a dual emission type, depending on the structure thereof. The sub-pixels SP refer to units capable of emitting light of their own colors with or without a specific type of color filter. For example, the sub-pixels SP may include red sub-pixels, green sub-pixels, and blue sub-pixels. Alternatively, the sub-pixels SP may include, for example, red sub-pixels, blue sub-pixels, white sub-pixels, and green sub-pixels. The sub-pixels SP may have one or more different emission areas depending on emission characteristics thereof. For example, blue sub-pixels and sub-pixels that emit other colors may have different emission areas.

One or more sub-pixels SP may constitute one unit pixel. For example, one unit pixel may include red, green, and blue sub-pixels, and the red, green, and blue sub-pixels may be repeatedly disposed. Alternatively, one unit pixel may include red, green, blue, and white sub-pixels, and the red, green, blue, and white sub-pixels may be repeatedly disposed or may be disposed in a quad type. However, the present disclosure is not limited thereto. In the embodiment according to the present disclosure, the color types, arrangement types, and arrangement orders of the sub-pixels may be configured in various forms depending on emission characteristics, lifespan of elements, or specifications of the device.

The display panel 11 may be divided into a display area AA (an area inside the dotted line) at which the sub-pixels SP are disposed to display an image and a non-display area NA surrounding the display area AA. The scan driver 15 may be mounted in the non-display area NA of the display panel 11. In addition, the non-display area NA may include a pad unit PAD including pad electrodes PD.

Hereinafter, the display area AA will be referred to as an active area, and the non-display area NA will be referred to as a non-active area.

The image processor 12 may output a data enable signal DE along with a data signal DATA supplied from the outside. In addition to the data enable signal DE, the image processor 12 may output at least one of a vertical sync signal, a horizontal sync signal, or a clock signal. However, illustration of these signals is omitted for convenience of description.

The timing controller 13 may receive the data signal DATA along with a driving signal from the image processor 12. The driving signal may include the data enable signal DE. Alternatively, the driving signal may include the vertical sync signal, the horizontal sync signal, and the clock signal. The timing controller 13 may output, based on the driving signal, a data timing control signal DDC for control of an operation timing of the data driver 14 and a gate timing control signal GDC for control of an operation timing of the scan driver 15.

The data driver 14 may sample and latch the data signal DATA supplied from the timing controller 13 in response to the data timing control signal DDC supplied from the timing controller 13, may convert the latched data signal into a gamma reference voltage, and may output the gamma reference voltage.

The data driver 14 may output the data signal DATA through the data lines DL. The data driver 14 may be implemented in the form of an integrated circuit (IC). For example, the data driver 14 may be electrically connected to the pad electrodes PD disposed in the non-active area NA of the display panel 11 via a flexible circuit film (not shown).

The scan driver 15 may output a scan signal in response to the gate timing control signal GDC supplied from the timing controller 13. The scan driver 15 may output the scan signal through the gate lines GL. The scan driver 15 may be implemented in the form of an integrated circuit (IC) or may be implemented on the display panel 11 in a gate-in-panel (GIP) manner.

The power supply 16 may output a high potential voltage and a low potential voltage for driving the display panel 11. The power supply 16 may supply the high potential voltage to the display panel 11 through a first power line EVDD (a driving power line or a pixel power line) and may supply the low potential voltage to the display panel 11 through a second power line EVSS (an auxiliary power line or a common power line).

The display panel 11 may be divided into the active area AA and the non-active area NA, and may include a plurality of sub-pixels SP defined by the gate lines GL and the data lines DL, which intersect each other in the form of a matrix in the active area AA.

The sub-pixels SP may include sub-pixels that emit at least two types of light among red light, green light, blue light, yellow light, magenta light, and cyan light. In addition, the plurality of sub-pixels SP may emit light of their own colors with or without a specific type of color filter. However, the present disclosure is not limited thereto. The color types, arrangement types, and arrangement orders of the sub-pixels SP may be configured in various forms depending on emission characteristics, lifespan of elements, or specifications of the device.

Each sub-pixel SP may include an emission portion, from which light is emitted, and a non-emission portion provided around the emission portion.

Hereinafter, a light emitting display device according to an embodiment of the present disclosure, which includes emission portions REM, GEM, BEM, and WEM that emit respective colors at a red sub-pixel RSP, a green sub-pixel GSP, a blue sub-pixel BSP, and a white sub-pixel WSP, will be described with reference to the accompanying drawings.

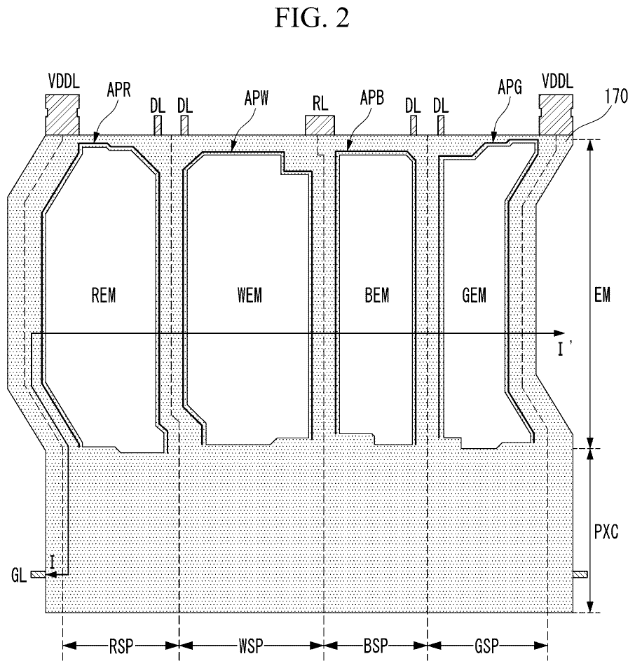

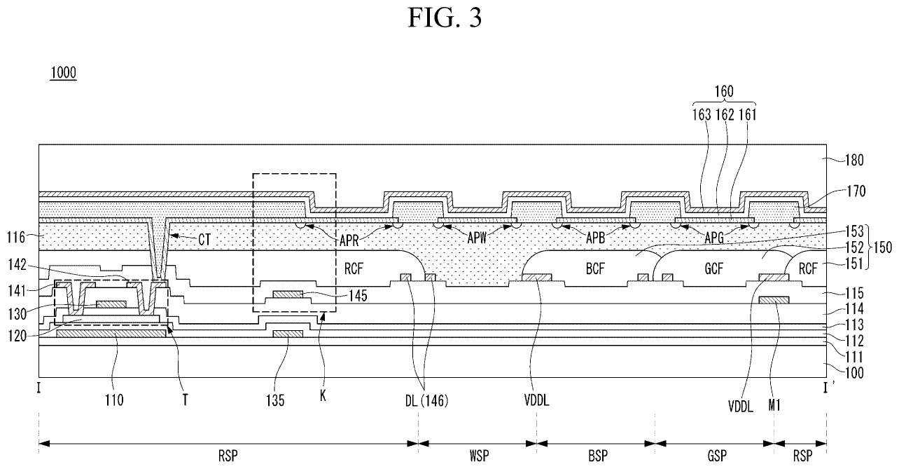

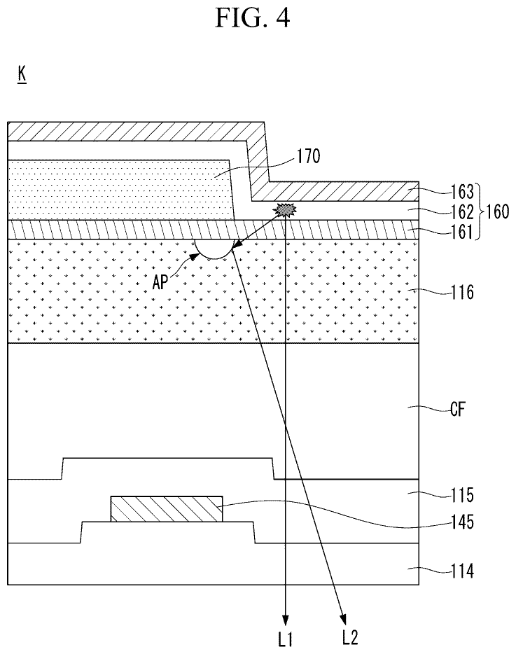

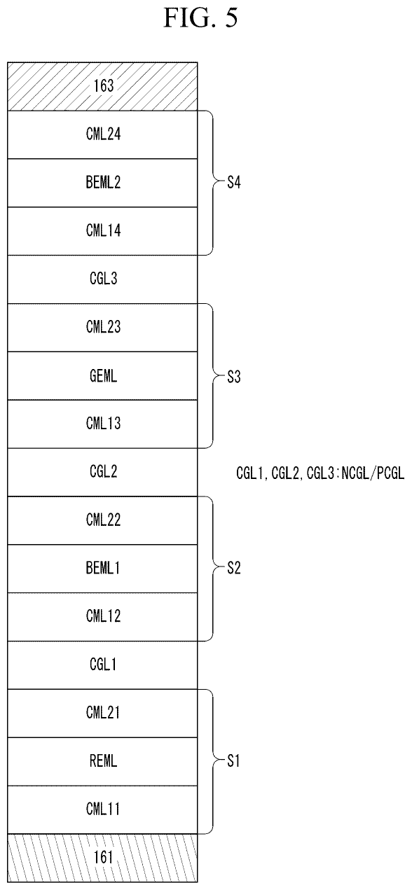

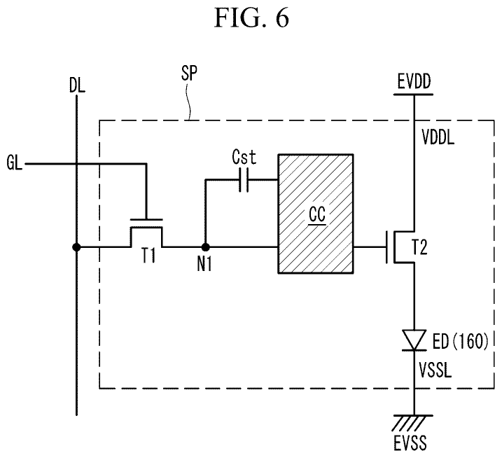

FIG. 2 is a plan view of the light emitting display device according to an example embodiment of the present disclosure. FIG. 3 is a cross-sectional view taken along line I-I′ in FIG. 2. FIG. 4 is an enlarged view of region K in FIG. 3. FIG. 5 is a cross-sectional view showing an example of a light emitting device included in the light emitting display device according to an example embodiment of the present disclosure. FIG. 6 is a circuit diagram of a sub-pixel according to an example embodiment of the present disclosure.

As shown in FIGS. 2 and 3, the light emitting display device 1000 according to the embodiment of the present disclosure may include a substrate 100 including a plurality of sub-pixels RSP, WSP, BSP, and GSP, a pixel circuit PXC disposed on the substrate 100, a planarization layer 116 covering the pixel circuit, a light emitting device 160, which is disposed on the planarization layer 116 at each of the plurality of sub-pixels RSP, WSP, BSP, and GSP and includes a first electrode 161 provided in an entire area of each of emission portions REM, WEM, BEM, and GEM and in part of a non-emission portion around the emission portion, a bank 170 disposed on the planarization layer 116 to expose the emission portion of the first electrode 161, and air pockets APR, APW, APB, and APG disposed on the surface of the planarization layer 116 below the bank 170.

As shown in FIG. 2, the air pockets APR, APW, APB, and APG are independently provided at the respective sub-pixels RSP, WSP, BSP, and GSP. That is, the air pocket APR provided at the red sub-pixel RSP, the air pocket APW provided at the white sub-pixel WSP, the air pocket APB provided at the blue sub-pixel BSP, and the air pocket APG provided at the green sub-pixel GSP are spaced apart from each other and function optically independently.

The air pockets APR, APW, APB, and APG may be disposed at the respective sub-pixels RSP, WSP, BSP, and GSP to overlap edges of the bank 170 and surround the emission portions REM, WEM, BEM, and GEM.

In the embodiments of the present disclosure, the air pockets APR, APW, APB, and APG refer to structures on the substrate 100 that contain air. As shown in FIG. 3, the air pockets APR, APW, APB, and APG refer to regions filled with air between the planarization layer 116 and the bank 170. The components on the substrate 100, excluding the air pockets APR, APW, APB, and APG, include predetermined materials.

The components on the substrate 100, excluding the air pockets APR, APW, APB, and APG, have a higher refractive index than air.

As shown in FIG. 2, each sub-pixel SP may be divided into an emission portion EM (REM, WEM, BEM, or GEM) and a pixel circuit PXC. As shown in FIG. 3, the bank 170 is disposed to open the emission portion EM (REM, WEM, BEM, or GEM) and to overlap the pixel circuit PXC.

The bank 170 may overlap the pixel circuit PXC, which includes a plurality of transistors T1 and T2 (see FIG. 6) and a storage capacitor Cst (see FIG. 6), and may also overlap various lines connected to the pixel circuit PXC, such as a gate line GL, a data line DL, a driving voltage line VDDL, and a low-voltage supply line VSSL (see FIG. 6).

The air pockets APR, APW, APB, and APG are disposed outside the respective emission portions REM, WEM, BEM, and GEM so as to surround the emission portions REM, WEM, BEM, and GEM, and are located in regions overlapping the bank 170. In an example shown in FIG. 2, the air pockets APR, APW, APB, and APG may be disposed along the remaining sides of the respective emission portions EM (REM, WEM, BEM, and GEM), excluding one side of each emission portion that is adjacent to a region in which the pixel circuit PXC is concentratedly disposed. In this case, in a plan view, the air pockets APR, APW, APB, and APG may have an inverted U-shape that is open at the bottom, as shown in FIG. 2.

The shape of the air pockets APR, APW, APB, and APG having open regions shown in FIG. 2 is merely one example. In some cases, the air pockets APR, APW, APB, and APG may be in a closed-loop shape without open regions.

In a plan view, each of the air pockets APR, APW, APB, and APG may be disposed as a single unit around a corresponding emission portion EM (REM, WEM, BEM, or GEM). In a plan view, each of the air pockets APR, APW, APB, and APG may be continuously and linearly disposed along three or more sides of a corresponding emission portion EM (REM, WEM, BEM, or GEM) without interruption.

In a cross-sectional view, curved interfaces may be defined between the lower surfaces of the air pockets APR, APW, APB, and APG and the upper surface of the planarization layer 116. For example, as shown in FIGS. 3 and 4, the air pockets APR, APW, APB, and APG have a semicircular cross-section. The semicircular cross-section of the air pockets APR, APW, APB, and APG shown in FIGS. 3 and 4 is merely one example, and the air pockets APR, APW, APB, and APG may have an arc-shaped cross-section. That is, in a cross-sectional view, the air pockets APR, APW, APB, and APG may have a partial circular shape below the lower surface of the bank 170.

It is advantageous that the interfaces between the lower surfaces of the air pockets APR, APW, APB, and APG and the upper surface of the planarization layer 116 have a curved shape rather than a straight shape. When light generated in the light emitting device 160 travels toward the curved lower surfaces of the air pockets APR, APW, APB, and APG, the light is refracted and reflected toward the planarization layer 116 from the interface between the air inside the air pockets APR, APW, APB, and APG and the planarization layer 116 outside the air pockets APR, APW, APB, and APG. As a result, the light may ultimately be emitted through the substrate 100.

The air pockets APR, APW, APB, and APG are provided by injecting air into the region between the bank 170 and the upper surface of the planarization layer 116.

Since the air pockets APR, APW, APB, and APG contain air, there is a difference in refractive index between a space in which the air pockets APR, APW, APB, and APG are disposed and surrounding components. That is, the air pockets APR, APW, APB, and APG are filled with air, and the upper surface of the planarization layer 116 forming a curved interface is disposed on the lower surfaces of the air pockets APR, APW, APB, and APG. Due to the refractive index difference between the air pockets APR, APW, APB, and APG and the planarization layer 116, light introduced into the air pockets APR, APW, APB, and APG, which are located in the non-emission portion, may be refracted and reflected by the upper surface (interface) of the planarization layer 116 facing the air pockets APR, APW, APB, and APG, and may then be directed toward the planarization layer 116 located in the emission portions REM, WEM, BEM, and GEM. The planarization layer 116 has a higher refractive index than air.

The light emitting device 160 has a stacked structure including a first electrode 161, an intermediate layer 162, and a second electrode 163. When the first electrode 161 includes a transparent electrode and the second electrode 163 includes a reflective electrode, first light L1 that travels vertically among the light generated in the light emitting device 160 may be transmitted through the emission portions REM, WEM, BEM, and GEM of the substrate 100.

In addition to the first light L1 that travels vertically, second light L2 may travel in a radial direction among the light generated in the light emitting device 160.

Light heading toward the second electrode 163 among the light generated in the radial direction may be reflected by the surface of the second electrode 163 in contact with the intermediate layer 162 and may travel toward the first electrode 161. This light may be emitted toward the substrate 100 together with the first light L1 that travels directly downward toward the first electrode 161 from the light emitting device 160. In the light emitting display device according to the embodiment of the present disclosure, the second light L2 traveling obliquely toward the outside of the emission portions REM, WEM, BEM, and GEM among the light generated in the radial direction is refracted and reflected by the curved interfaces between the air pockets APR, APW, APB, and APG and the planarization layer 116, and then travels toward the emission portions REM, WEM, BEM, and GEM, thereby increasing the total amount of light emitted.

Therefore, in the light-emitting display device according to embodiment of the present disclosure, among the light generated in the light emitting device 160, not only the direct light traveling in the vertical direction but also the light traveling in the oblique direction may be output through refraction and reflection using the curved surfaces of the air pockets APR, APW, APB, and APG, thereby improving light extraction efficiency.

In a structure that does not include the air pockets APR, APW, APB, and APG, among the light generated in the light emitting device, the light traveling in the oblique direction toward the region outside the emission portions may be absorbed by lines or transistor structures on the substrate or may be totally internally reflected and lost without contributing to light extraction. Alternatively, the light emitted in the oblique direction from the light emitting device may enter adjacent sub-pixels and cause color mixing.

In contrast, in the light emitting display device according to the embodiment of the present disclosure, the light emitted in the oblique direction from the emission portions of the light emitting device may have its propagation direction altered by the curved surfaces of the air pockets APR, APW, APB, and APG and may be utilized for light extraction. This maximizes or increases the use of the light generated in the light emitting device, thereby improving the light extraction efficiency of the display panel. In addition, in the light emitting display device according to the embodiment of the present disclosure, the light traveling in the oblique direction from the emission portions toward adjacent sub-pixels may be refracted by the curved surfaces of the air pockets to be directed back toward the emission portions. Accordingly, it is possible to prevent or suppress the light emitted from the light emitting device from causing color mixing at adjacent sub-pixels.

The air pockets APR, APW, APB, and APG may be disposed on an upper side of the planarization layer 116 and may overlap the bank 170 disposed thereon.

The bank 170 is a component defining the emission portions REM, WEM, BEM, and GEM of the light emitting device 160. The emission portion of the first electrode 161 of the light emitting device 160 may be exposed through an opening of the bank 170.

As shown in FIGS. 2 to 4, the air pockets APR, APW, APB, and APG independently disposed at the respective sub-pixels RSP, WSP, BSP, and GSP may allow the light L2 traveling from the light emitting device 160 toward the non-emission portions of the respective sub-pixels RSP, WSP, BSP, and GSP to be refracted and reflected by the interfaces between the lower surfaces of the air pockets APR, APW, APB, and APG and the planarization layer 116 and to travel toward the emission portions of the respective sub-pixels RSP, WSP, BSP, and GSP. In this way, the light traveling toward the non-emission portions may be utilized for light extraction, rather than being absorbed by the non-emission portions, thereby improving light extraction efficiency.

FIG. 2 shows an example in which a red emission portion REM, a white emission portion WEM, a blue emission portion BEM, and a green emission portion GEM are disposed from left to right in that order. However, the embodiments of the present disclosure are not limited thereto.

Although the red emission portion REM and the white emission portion WEM are illustrated in FIG. 2 as being larger in size than the blue emission portion BEM and the green emission portion GEM, the light emitting display device according to the embodiment of the present disclosure is not limited thereto. When white light emission is performed in the light emitting display device, the areas of the emission portions may be adjusted in consideration of the emission ratio or the efficiency of emission layers provided in the respective emission portions.

The bank 170 that exposes the emission portions REM, WEM, BEM, and GEM may overlap a data line DL, a driving voltage line VDDL, and a gate line GL as well as a plurality of transistors and a storage capacitor.

The data line DL may be provided at each of the sub-pixels RSP, WSP, BSP, and GSP, which include the emission portions REM, WEM, BEM, and GEM. The data lines DL may be disposed adjacent to the non-emission portions at two adjacent ones of the sub-pixels. In the illustrated example, two data lines DL are disposed between the red emission portion REM and the white emission portion WEM, and two data lines DL are disposed between the blue emission portion BEM and the green emission portion GEM. In this case, sub-pixels on both sides of the neighboring data lines may have symmetrical arrangements of transistors in the pixel circuit PXC.

However, the light emitting display device of the present disclosure is not limited to the data line arrangement shown in FIG. 2. The data lines may be disposed at the respective sub-pixels while being spaced apart at regular intervals. An image signal is applied to the data lines DL while being periodically updated.

The driving voltage line VDDL may be provided at each of n (n being a natural number) sub-pixels RSP, WSP, BSP, and GSP. The driving voltage line VDDL disposed in the Y-axis direction may include branch portions extending in the X-axis direction toward adjacent sub-pixels, so that a high-potential driving voltage EVDD may be applied through the same driving voltage line VDDL. Although the driving voltage line VDDL is illustrated as being provided at each of four sub-pixels, the embodiments of the present disclosure are not limited thereto. A reference line RL may be disposed at the non-emission portion in which the driving voltage line VDDL is not disposed.

The driving voltage line VDDL, to which a high-potential voltage signal is applied, may have a greater line width than the data line DL to reduce line resistance during application of the high-potential driving voltage signal, thereby preventing or reducing a voltage difference between regions.

The air pockets APR, APW, APB, and APG are located at the edges of the respective emission portions REM, WEM, BEM, and GEM, thereby allowing light traveling toward the lower side of the bank 170 among the light emitted from the light emitting device 160 toward the substrate 100 to be directed toward the emission portions REM, WEM, BEM, and GEM of the respective sub-pixels.

Hereinafter, the components of the light emitting display device 1000 of the present disclosure will be described in more detail.

The substrate 100 may include at least one of a glass base, a plastic layer, or a metal plate having a predetermined supporting strength. The substrate 100 may comprise a flexible material. For example, when the substrate 100 has a multilayer structure, the substrate 100 may have a stacked structure including a first organic layer, an inorganic insulating layer, and a second organic layer. The first organic layer disposed at the outermost position may function to prevent the introduction of external impurities and to provide protection. The second organic layer may enable planarization of the surface on which the internal array structure is provided and may prevent or suppress the transfer of charges or impurities from the outside to the inside. The inorganic insulating layer between the first and second organic layers may function to prevent or suppress permeation or diffusion of moisture between the first and second organic layers and the transfer of conductive impurities to the second organic layer.

The sub-pixels RSP, WSP, BSP, and GSP described in the present disclosure refer to a plurality of divided regions disposed within an active area AA on the substrate 100. The sub-pixels RSP, WSP, BSP, and GSP include emission portions REM, WEM, BEM, and GEM, respectively, and further include non-emission portions provided around the respective emission portions REM, WEM, BEM, and GEM.

The non-emission portions may be regions defined by the bank 170 that defines the emission portions REM, WEM, BEM, and GEM of the sub-pixels. The bank 170 is disposed in the non-emission portions and exposes the emission portions REM, WEM, BEM, and GEM of the first electrodes 161 disposed at the respective sub-pixels RSP, WSP, BSP, and GSP. The bank 170 is disposed to cover an edge of each first electrode 161. The bank 170 has openings, through which the emission portions REM, WEM, BEM, and GEM are exposed.

The bank 170 may include a light-shielding organic material that absorbs or blocks at least a portion of wavelengths in the visible spectrum. The light-shielding organic material of the bank 170 refers to a material that absorbs light, and includes an organic material that absorbs at least a portion of wavelengths in the visible spectrum. The bank 170 may include a material such as black carbon or a color pigment. The bank 170 may comprise a stacked structure including a light-shielding organic material layer and a light-transmitting organic material layer.

In the light emitting display device 1000, a pixel circuit including a plurality of transistors T and at least one storage capacitor may be provided at each of the sub-pixels RSP, WSP, BSP, and GSP on the substrate 100, and may be selectively driven. Although FIG. 3 illustrates, as an example, that one transistor T is provided at each of the sub-pixels RSP, WSP, BSP, and GSP), each sub-pixel may include two or more transistors as needed. The pixel circuit at each of the sub-pixels RSP, WSP, BSP, and GSP may include at least one switching transistor configured to control turn-on of each of the sub-pixels RSP, WSP, BSP, and GSP and a driving transistor configured to supply a driving current to the light emitting device 160.

The transistor T includes an active layer 120, a gate electrode 130 overlapping a portion of the active layer 120, and first and second source/drain electrodes 141 and 142 that are spaced apart from each other and connected to the active layer 120. A light-shielding pattern 110 may further be provided below the transistor T to prevent or protect the active layer 120 from being affected by light entering the substrate 100. It is advantageous that the light-shielding pattern 110 be disposed to have an area that is equal to or greater than that of the channel region of the active layer 120. In some cases, the light-shielding pattern 110 may be omitted.

A plurality of insulating layers 111, 112, 113, 114, 115, and 116 may be provided on the substrate 100.

A first insulating layer 111 may function as a buffer layer or an active buffer layer. The buffer layer or the active buffer layer may serve to prevent or suppress impurities from being transmitted upward from below the lines and the active layer included in the internal array and to support and protect the overlying components. The first insulating layer 111 may be provided in a multilayer structure.

The transistor T and the storage capacitor may be disposed on the first insulating layer 111 at each of the sub-pixels RSP, WSP, BSP, and GSP.

The light-shielding pattern 110 may be provided on the first insulating layer 111 to prevent or suppress light from being transmitted from below to the active layer 120 of the transistor T.

A second insulating layer 112 may be disposed between the light-shielding pattern 110 and the active layer 120 to achieve insulation.

The transistor T may be disposed on the second insulating layer 112 at each of the plurality of sub-pixels. For example, the transistor T may include an active layer 120, a gate electrode 130 that overlaps the active layer 120 with a third insulating layer 113 interposed therebetween, and first and second source/drain electrodes 141 and 142 connected to both sides of the active layer 120.

As one example, the storage capacitor may include a first storage electrode and a second storage electrode that overlap each other. At least one of the first storage electrode or the second storage electrode may be made of the same material as the active layer 120, and the other may include the same material as at least one of the gate electrode 130, the first source/drain electrode 141, the second source/drain electrode 142, or the light-shielding pattern 110.

The third insulating layer 113 interposed between the active layer 120 and the gate electrode 130 may function as a gate insulating layer.

The active layer 120 may include, for example, a silicon-based or oxide semiconductor. The silicon-based semiconductor may include crystalline and/or amorphous silicon. The oxide semiconductor may include at least one of gallium oxide, tin oxide, zinc oxide, indium oxide, iron oxide, or indium-gallium-zinc oxide. In some cases, the oxide semiconductor layer may include multiple layers comprising different materials or materials having different composition ratios. Each sub-pixel may include a plurality of thin film transistors, and the thin film transistors may be located on different layers. For example, each sub-pixel of the substrate 100 may include a plurality of thin film transistors having different active layers. As one example, a first thin film transistor may include a silicon-based active layer and may be disposed closer to the substrate 100, and a second thin film transistor may be disposed above the first thin film transistor and may include an oxide semiconductor as an active layer.

The active layer 120 may include a channel region overlapping the gate electrode 130 and source/drain regions respectively connected to the first and second source/drain electrodes 141 and 142.

The third insulating layer 113 may be selectively disposed on the channel region of the active layer 120 so as to correspond thereto or may be provided across the entire surface of the substrate 100 except for the regions through which the first and second source/drain electrodes 141 and 142 pass. The third insulating layer 113 may function to electrically insulate the active layer 120 and the gate electrode 130 from each other. The third insulating layer 113 may comprise an inorganic insulating material and may be implemented as, for example, a silicon oxide (SiOx) layer, a silicon nitride (SiNx) layer, a silicon oxynitride (SiOxNy) layer, or a multilayer layer thereof.

The gate electrode 130 may be provided on the third insulating layer 113. The gate electrode 130 may be disposed to face the active layer 120 with the third insulating layer 113 interposed therebetween.

A fourth insulating layer 114 may be provided on the gate electrode 130 to cover and protect the gate electrode 130. The fourth insulating layer 114 may function to protect at least one electrode of the transistor T, such as the gate electrode 130 and the active layer 120. The fourth insulating layer 114 may comprise an inorganic insulating material. For example, the fourth insulating layer 114 may be implemented as a silicon oxide (SiOx) layer, a silicon nitride (SiNx) layer, a silicon oxynitride (SiOxNy) layer, or a multilayer layer thereof.

The first source/drain electrode 141 and the second source/drain electrode 142 may be disposed on the fourth insulating layer 114. The fourth insulating layer 114 and the third insulating layer 113 may include contact holes disposed by removing regions thereof corresponding thereto, so that the first and second source/drain electrodes 141 and 142 are in contact with respective ends of the active layer 120.

The gate electrode 130 and the first and second source/drain electrodes 141 and 142 may be provided in a single-layer structure or a multilayer structure.

When the gate electrode 130 and the first and second source/drain electrodes 141 and 142 are provided in a single-layer structure, the gate electrode 130 and the first and second source/drain electrodes 141 and 142 may comprise any one selected from the group consisting of molybdenum (Mo), aluminum (Al), chromium (Cr), gold (Au), titanium (Ti), nickel (Ni), neodymium (Nd), and copper (Cu), or an alloy thereof. Alternatively, when the gate electrode 130 and the first and second source/drain electrodes 141 and 142 are provided in a multilayer structure, the gate electrode 130 and the first and second source/drain electrodes 141 and 142 comprise a bilayer structure such as molybdenum/aluminum-neodymium, molybdenum/aluminum, titanium/aluminum, or copper/molybdenum-titanium. Alternatively, the gate electrode 130 and the first and second source/drain electrodes 141 and 142 may comprise a tri-layer structure such as molybdenum/aluminum-neodymium/molybdenum, molybdenum/aluminum/molybdenum, titanium/aluminum/titanium, or molybdenum-titanium/copper/molybdenum-titanium.

However, the present disclosure is not limited thereto. The gate electrode 130 and the first and second source/drain electrodes 141 and 142 may be provided in a multilayer structure, each layer independently selected from the group consisting of molybdenum (Mo), aluminum (Al), chromium (Cr), gold (Au), titanium (Ti), nickel (Ni), neodymium (Nd), and copper (Cu), or an alloy thereof.

For example, the gate line GL, the data line DL, the reference line RL, the driving voltage line VDDL, and other metal lines 135 and 145 or a metal pattern M1 may be disposed on the same layer as at least one of the light-shielding pattern 110, the gate electrode 130, the first source/drain electrode 141, or the second source/drain electrode 142.

Even when the gate line GL, the data line DL, the reference line RL, the driving voltage line VDDL, and other metal lines 135 and 145 or the metal pattern M1 partially overlap the air pockets APR, APW, APB, and APG, light may be reflected by the curved interface between the air pockets APR, APW, APB, and APG and the planarization layer 116, and may be emitted through the emission portions REM, WEM, BEM, and GEM during light extraction.

A fifth insulating layer 115 may further be provided on the transistor T to protect the transistor T. The fifth insulating layer 115 may comprise an inorganic insulating layer. In some cases, the fifth insulating layer 115 may be omitted.

Each of the first to fifth insulating layers 111, 112, 113, 114, and 115 may comprise an inorganic insulating layer. The inorganic insulating layer may be, for example, at least one of a silicon oxide layer, a silicon nitride layer, or a silicon oxynitride layer.

A red color filter RCF, a blue color filter BCF, and a green color filter GCF may be provided on the fifth insulating layer 115 corresponding to the red sub-pixel RSP, the blue sub-pixel BSP, and the green sub-pixel GSP. The red color filter RCF may include a color pigment that selectively transmits red light. The blue color filter BCF may include a color pigment that selectively transmits blue light. The green color filter GCF may include a color pigment that selectively transmits green light.

Each of the red, blue, and green color filters RCF, BCF, and GCF may comprise an organic insulating material that selectively transmits light of a predetermined wavelength and absorbs or blocks light of other wavelengths.

The planarization layer 116 for planarization may be disposed on the fifth insulating layer 115 on which the red color filter RCF, the blue color filter BCF, and the green color filter GCF are disposed. The planarization layer 116 may planarize a surface on which the first electrode 161 is provided.

As shown in FIGS. 2 and 3, the air pockets APR, APW, APB, and APG are linearly disposed outside the emission portions REM, WEM, BEM, and GEM on the upper surface of the planarization layer 116 so as to surround the emission portions REM, WEM, BEM, and GEM. While portions of the upper surface of the planarization layer 116 on which the emission portions REM, WEM, BEM, and GEM are disposed are flat, portions of the upper surface of the planarization layer 116 within the region overlapping the bank 170 may be curved toward the substrate 100.

As shown in FIG. 3, each of the air pockets APR, APW, APB, and APG may overlap one end of the first electrode 161. The lower surface of the first electrode 161 and the lower surface of the bank 170 outside one end of the first electrode 161, which are located at the same vertical level, may overlap the upper side of each of the air pockets APR, APW, APB, and APG. In this case, air is disposed between the lower surface of the first electrode 161 and the curved surface of the planarization layer 116 and between the lower surface of the bank 170 and the curved surface of the planarization layer 116.

Alternatively, the lower surface of the first electrode 161 may be disposed on the entire upper side of each of the air pockets APR, APW, APB, and APG. In this case, air in the air pockets APR, APW, APB, and APG is disposed between the lower surface of the first electrode 161 and the curved surface of the planarization layer 116.

A maximum depth H of the air pockets AP (APR, APW, APB, and APG) refers to a distance from the insulating layer IN2 including the planarization layer (the flat upper surface of the planarization layer based on FIG. 3) to a deepest point recessed toward the substrate 100.

In a cross-sectional view, the maximum depth of the air pockets APR, APW, APB, and APG is 1 μm or less, which is less than the overall thickness of the planarization layer 116. In some embodiments, the maximum depth of the air pockets APR, APW, APB, and APG is equal to or greater than 200 nm and less than 1 μm. The planarization layer 116 has a thickness ranging from approximately 1.5 μm to approximately 5 μm, and the curved surface (upper surface) of the planarization layer 116 is located on the lower surface of each of the air pockets APR, APW, APB, and APG.

Because no color filter is disposed at the white sub-pixel WSP, the planarization layer 116 disposed at the white sub-pixel WSP may be thicker than the planarization layer 116 disposed at the red, green, and blue sub-pixels RSP, GSP, and BSP.

The planarization layer 116 may include an organic material. The organic material may include at least one of acrylic resin, phenolic resin, polyimide resin, unsaturated polyester resin, polyamide resin, benzocyclobutene, polyphenylene resin, or polyphenylene sulfide resin. The planarization layer 116 may have a refractive index ranging from approximately 1.35 to approximately 1.8.

A contact hole CT may be provided in the planarization layer 116, the color filters RCF, BCF, and GCF, and the fifth insulating layer 115 disposed on the second source/drain electrode 142 of the transistor T at each of the sub-pixels RSP, WSP, BSP, and GSP, such that a portion of the second source/drain electrode 142 may be exposed.

The first electrode 161 of the light emitting device 160 may be electrically connected to the second source/drain electrode 142 of the transistor T through the contact hole CT at each of the sub-pixels RSP, WSP, BSP, and GSP.

The light emitting device 160 includes a stacked structure of the first electrode 161, the intermediate layer 162, and the second electrode 163.

The light emitting display device 1000 may be of a bottom emission type. The first electrode 161 of the light emitting device 160 may include a transparent oxide electrode such as indium tin oxide (ITO), indium zinc oxide (IZO), or indium tin zinc oxide (ITZO), and the second electrode 163 may include a reflective electrode.

The second electrode 163 may include a single-layer structure of at least one selected from among aluminum (Al), silver (Ag), molybdenum (Mo), gold (Au), magnesium (Mg), calcium (Ca), and barium (Ba), or an alloy of two or more thereof.

An edge of the first electrode 161 may overlap the bank 170 and may overlap a portion or the entirety of the air pockets APR, APW, APB, and APG. In the region in which the first electrode 161 overlaps the air pockets APR, APW, APB, and APG, the lower surface of the bank 170 is in contact with the upper surface of the first electrode 161, and air in the air pockets APR, APW, APB, and APG is present between the lower surface of the first electrode 161 and the upper surface of the planarization layer 116 that defines an interface with the air pockets APR, APW, APB, and APG.

As shown in FIG. 5, as one example, the intermediate layer 162 may include a plurality of light emitting stacks S1, S2, S3, and S4 and charge generation layers CGL1, CGL2, and CGL3 disposed between the light emitting stacks, which are commonly provided at the sub-pixels RSP, WSP, BSP, and GSP. The light emitting device 160 in each of the sub-pixels RSP, WSP, BSP, and GSP may commonly emit white light, and red light, blue light, and green light may be emitted through the red color filter RCF, the blue color filter BCF, and the green color filter GCF provided at the red sub-pixel RSP, the blue sub-pixel BSP, and the green sub-pixel GSP, respectively.

As one example, the intermediate layer 162 may be configured such that a first light emitting stack S1 that emits red light, a second light emitting stack S2 that emits blue light, a third light emitting stack S3 that emits green light, and a fourth light emitting stack S4 that emits blue light are stacked in that order. That is, the intermediate layer 162 shown in FIG. 5 has a configuration in which the R/B1/G/B2 light emitting stacks are sequentially stacked in a direction from the first electrode 161 toward the second electrode 163. As shown in FIG. 5, although the same light emitting device 160 is commonly included at the sub-pixels RSP, WSP, BSP, and GSP, because the red color filter RCF, the blue color filter BCF, and the green color filter GCF are disposed between the light emitting device 160 and the substrate 100, it is possible to achieve individual color representation different from white at each of the sub-pixels RSP, BSP, and GSP and to represent white light emitted from the light emitting element 160 at the white sub-pixel WSP that does not include a color filter.

FIG. 5 shows an example in which the intermediate layer 162 includes four light emitting stacks and three charge generation layers.

However, the light emitting device according to the embodiment of the present disclosure is not limited thereto. For example, unlike the example shown in FIG. 5, in which the light emitting stacks are sequentially disposed in the order of R/B1/G/B2 between the first electrode and the second electrode, the red light emitting stack, the green light emitting stack, and the first and second blue light emitting stacks may be sequentially disposed, that is, in the order of R/G/B1/B2, between the first electrode and the second electrode. Alternatively, the green light emitting stack, the red light emitting stack, and the first and second blue light emitting stacks may be sequentially disposed, that is, in the order of G/R/B1/B2, between the first electrode and the second electrode. Alternatively, the first blue light emitting stack, the red light emitting stack, the green light emitting stack, and the second blue light emitting stack may be sequentially disposed, that is, in the order of B1/R/G/B2, between the first electrode and the second electrode. Alternatively, the light emitting stacks may be stacked in various other orders.

The reason why two light emitting stacks that emit blue light are provided in the light emitting device is to compensate for the relatively low efficiency of blue emission compared to other colors.

The light emitting device including the first to fourth light emitting stacks S1, S2, S3, and S4 described above may emit white light when a voltage equal to or greater than a certain level is applied between the first electrode 161 and the second electrode 163.

The intermediate layer of the light emitting device 160 may have a configuration in which the plurality of light emitting stacks and the charge generation layers are disposed in a manner different from the illustrated example.

Alternatively, a plurality of emission layers may be disposed in the intermediate layer 162 of the light emitting device 160 in such a manner that a red emission layer is disposed at the red sub-pixel, a green emission layer is disposed at the green sub-pixel, a blue emission layer is disposed at the blue sub-pixel, and a plurality of emission layers is included at the white sub-pixel and is combined to emit white light. In this case, in addition to the color emission layers, the intermediate layer 162 may include common layers that have hole-transporting properties and are disposed between the first electrode 161 and the color emission layers and common layers that have electron-transporting properties and are located between the color emission layers and the second electrode 163.

An encapsulation layer 180 is provided on the light emitting device 160 to protect the light emitting device 160.

For example, the encapsulation layer 180 may include one or more inorganic encapsulation layers and one or more organic encapsulation layers alternately disposed.

The configuration of the pixel circuit shown in FIG. 2 will be described in detail with reference to FIG. 6.

As shown in FIG. 6, each of the sub-pixels SP (RSP, WSP, BSP and GSP) in the active area AA may include, for example, a first transistor T1, a second transistor T2, a storage capacitor Cst, a compensation circuit CC, and a light emitting device ED (refer to 160 in FIGS. 3 and 4).

As one example, the first transistor T1 may be a switching transistor, and the second transistor T2 may be a driving transistor.

A first source/drain electrode (e.g., a drain electrode) of the first transistor T1 is electrically connected to a data line DL, and a second source/drain electrode (e.g., a source electrode) of the first transistor T1 is electrically connected to a first node N1. A gate electrode of the first transistor T1 is electrically connected to a gate line GL. The first transistor T1 transfers a data signal supplied through the data line DL to the first node N1 in response to a scan signal supplied through the gate line GL.

The storage capacitor Cst is electrically connected to the first node N1 and is charged with the voltage applied to the first node N1.

A first source/drain electrode (e.g., a drain electrode) of the second transistor T2 receives a high-voltage power supply voltage EVDD as a high-potential driving voltage through a driving voltage line VDDL, and a second source/drain electrode (e.g., a source electrode) of the second transistor T2 is electrically connected to a first electrode (e.g., an anode AND) of the light emitting device ED. The second transistor T2 may control an amount of driving current flowing through the light emitting device ED in response to the voltage applied to the gate electrode.

A semiconductor layer of the first transistor T1 and/or the second transistor T2 may include silicon such as amorphous silicon (a-Si), polycrystalline silicon (poly-Si), or low-temperature polycrystalline silicon (LTPS) or may include an oxide such as indium gallium zinc oxide (IGZO). However, the present disclosure is not limited thereto. At least one of the first transistor T1 or the second transistor T2 may include an oxide semiconductor layer, and thus may enable relatively low-temperature processing compared to other materials and may exhibit high mobility while maintaining amorphous characteristics.

The light emitting device ED (refer to 160 in FIGS. 3 and 4) outputs light corresponding to the driving current. The light emitting device ED may output light corresponding to any one of red, green, blue, and white.

The light emitting device ED (160) may include a first electrode 161, an intermediate layer 162 disposed on the first electrode 161, and a second electrode 163 configured to supply a common voltage. As described above with reference to FIG. 5, the intermediate layer 162 may include a plurality of common layers and one or more emission layers.

The second electrode 163 of the light emitting device ED (160) receives a low-potential voltage EVSS or a ground voltage through a low-potential voltage line VSSL. The low-potential voltage line VSSL may be disposed and included in a non-active area NA. In some cases, to prevent or suppress non-uniformity of the low-potential voltage EVSS generated in the active area AA, the low-potential voltage line VSSL may also be disposed in the active area AA. The low-potential voltage EVSS is also referred to as a common voltage.

The compensation circuit CC may be provided at the sub-pixel SP to compensate for the threshold voltage of the second transistor T2. The compensation circuit CC may include one or more transistors. The compensation circuit CC may include one or more transistors and capacitors. The compensation circuit CC may be configured in various forms depending on the compensation method. The sub-pixel including the compensation circuit CC may include various circuit structures, such as 3T1C, 4T2C, 5T2C, 6T1C, 6T2C, 7T1C, or 7T2C, with different numbers of transistors and/or capacitors.

The pixel circuit of the sub-pixel shown in FIG. 4 may be provided at each sub-pixel. The transistor TFT shown in FIG. 3 may, for example, correspond to the second transistor T2 shown in FIG. 6.

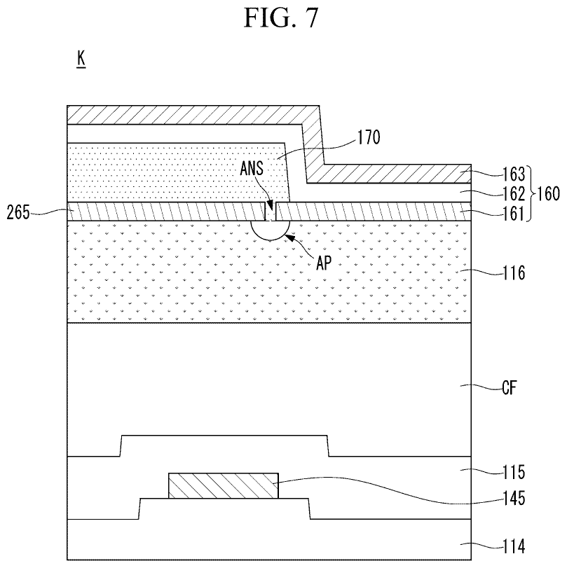

FIG. 7 is an enlarged view of region K in FIG. 3 according to another example embodiment.

FIG. 7 shows an example in which a first electrode 161 and a first electrode dummy pattern 265 are adjacent to each other below the bank 170 and a slit ANS by which the first electrode 161 and the first electrode dummy pattern 265 are spaced apart from each other overlaps an air pocket AP.

In this case, the air pocket AP overlaps both a part of the first electrode 161 and a part of the first electrode dummy pattern 265 that are located at the same vertical level.

The first electrode 161 and the first electrode dummy pattern 265 may be provided with the same material.

A plurality of insulating layers 114 and 115, a pixel circuit (refer to PXC in FIG. 2), and a plurality of metal lines 145 or a metal pattern are disposed on the substrate 100. A color filter CF for color representation of each of the emission portions REM, BEM, and GEM is disposed on the substrate 100. A planarization layer 116 is disposed on the color filter CF. The insulating layers 114 and 115 can be inorganic insulating layers and the planarization layer 116 can be an organic insulating layer.

The air pocket AP is provided by etching a part of the upper surface of the planarization layer 116 in a curved shape toward the substrate 100.

The air pocket AP overlaps a part of the first electrode 161, a part of the first electrode dummy pattern 265, and the slit ANS therebetween, which are disposed on the planarization layer 116, and also overlaps the bank 170. In this case, the width of the slit ANS corresponds to a portion of the width of the air pocket AP. During the process of forming the first electrode 161 and the first electrode dummy pattern 265, the air pocket AP is disposed by etching the planarization layer 116 through the slit ANS. During a subsequent process of forming the bank, a bank material does not flow into the narrow slit ANS, thereby maintaining the empty space in the air pocket AP. The formation of the air pocket AP may be carried out as follows.

After a first electrode forming material is placed on the planarization layer 116, a photosensitive layer is formed on the first electrode forming material so as to expose a region corresponding to the slit ANS. The first electrode forming material is patterned using an etchant to form the first electrode 161 at each sub-pixel and the first electrode dummy pattern 265 in a non-emission portion NEM, which is spaced apart from the first electrode 161 by the slit ANS. Subsequently, the photosensitive layer is removed.

Thereafter, a portion of the planarization layer 116 is isotropically etched through the slit ANS using an etchant having a different etch selectivity from that used for patterning the first electrode forming material. As a result, a region having a semicircular or arc shape and a larger width than the slit ANS is etched into the upper surface of the planarization layer 116 below the slit ANS, and this etched region is defined as the air pocket AP. Accordingly, the material of the planarization layer is removed from the region of the air pocket AP, and the region is filled with air.

The first electrode dummy pattern 265 is adjacent to, but electrically isolated from, the first electrode 161, and is in a floating state. As shown in FIG. 2, when the air pocket AP has a closed-loop shape in a plan view, the first electrode dummy pattern 265 is electrically isolated from the first electrode 161, which completely overlaps each of the emission portions REM, WEM, BEM, and GEM, with the slit ANS overlapping the air pocket AP interposed therebetween. As shown in FIG. 2, if the air pocket AP is not provided along one side of the emission portion EM at each of the sub-pixels RSP, WSP, BSP, and GSP, the first electrode 161 overlapping the emission portion EM and the first electrode 161 overlapping the non-emission portion may be electrically connected to each other in the region in which the air pocket AP is not provided.

The slit ANS between the first electrode 161 and the first electrode dummy pattern 265 is a very narrow gap. A material for forming the bank 170, which is placed on an edge of the first electrode 161 and on the first electrode dummy pattern 265, does not flow into the slit ANS between the first electrode 161 and the first electrode dummy pattern 265, so that the air pocket AP is maintained in a state of being filled with air. Accordingly, after the light emitting device 160 is provided, the curved interface between the lower surface of the air pocket AP and the planarization layer 116 functions to refract and reflect the light emitted from the light emitting device 160 toward the emission portion due to the difference in refractive index between the air in the air pocket AP and the planarization layer 116.

The light emitting display device of the present disclosure includes the air pocket AP below the bank 170, which is a structure defining the emission portion on the substrate, thereby adjusting the emission direction of the light that travels from the light emitting device in the radial direction. Accordingly, reflection or absorption of the light, generated from the intermediate layer 162 on the bank 170, within the substrate 100 may be reduced, and light extraction efficiency may be improved toward the emission portions EM (REM, WEM, BEM, and GEM).

The light emitting display device of the present disclosure may reduce or prevent the light emitted in the radial direction from the light emitting device from traveling toward the lines (metal lines) 145 within the substrate 100 or toward the components of the transistor. In addition, the light extraction direction may be changed by the curved surface of the air pocket AP so as not to interfere with a metal or active layer, thereby increasing the light extraction rate through the substrate 100.

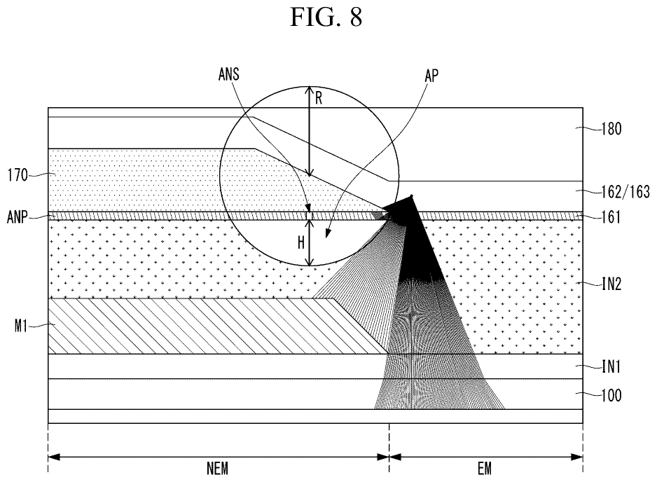

FIG. 8 is a view showing a relationship between the maximum depth of the air pocket and the curvature of the air pocket according to example embodiments of the present disclosure.

As shown in FIG. 8, the maximum depth H of the air pocket AP is proportional to the radius R of an imaginary circle having an arc corresponding to the curved surface of the air pocket AP that forms an interface with the upper surface of the insulating layer IN2 including the planarization layer. In this case, the radius of the imaginary circle is also referred to as a “curvature” of the curved surface of the air pocket AP.

The maximum depth H of the air pocket AP refers to a distance from the insulating layer IN2 including the planarization layer (the flat upper surface of the planarization layer based on FIG. 3) to a deepest point recessed toward the substrate 100.

When light is emitted from the intermediate layer 162 of the light emitting device 160, the light is emitted in the radial direction. Among the light emitted in the radial direction, light traveling in the downward vertical direction is directly output through the substrate 100, and light traveling in the upward vertical direction is reflected by the second electrode 163 and then travels in the downward vertical direction. When the light emitted in the radial direction travels toward the air pocket AP, the light is reflected by the curved interface between the lower surface of the air pocket AP and the upper surface of the insulating layer IN2 including the planarization layer, and then travels toward the emission portion of the sub-pixel that does not overlap the bank 170.

Table 1 below shows the relationship between the curvature R of the curved surface of the air pocket AP and the maximum depth H of the air pocket AP.

TABLE 1

| R[nm] | H[nm] |
|---|---|
| 395 | 210 |
| 459 | 236 |
| 510 | 266 |
| 567 | 295 |
| 629 | 321 |
| 681 | 355 |
| 739 | 383 |
| 804 | 410 |
| 863 | 436 |
| 906 | 468 |
| 976 | 494 |
| 1032 | 524 |
| 1095 | 553 |
| 1151 | 579 |
| 1211 | 609 |
| 1262 | 639 |
| 1321 | 669 |
| 1375 | 698 |
| 1493 | 754 |
| 1669 | 841 |
| 1896 | 953 |

As shown in Table 1 above, the maximum depth H of the air pocket is substantially linearly proportional to the curvature R of the air pocket. The maximum depth H of the air pocket is approximately 0.5 times the curvature R of the air pocket, indicating that the air pocket has a shape similar to an arc, which corresponds to a portion of a circle that is smaller than a semicircle in a cross-sectional view.

In addition, the light emitted in the radial direction from the intermediate layer 162 is refracted and reflected by the curved interface between the air pocket AP and the upper surface of the planarization layer, thereby increasing the amount of light traveling toward the emission portion of the substrate 100. As a result, the amount of light absorbed by the metal lines or the metal pattern M1 between the insulating layers IN1 and IN2 on the substrate 100 may be reduced, and accordingly, the light extraction efficiency of the light emitting display device may be enhanced.

FIG. 8 shows an example in which a first electrode 161 and a first electrode dummy pattern ANP (The first electrode dummy pattern ANP can be the first electrode dummy pattern 265 illustrated in FIG. 7.) are adjacent to each other below a bank 170 and a separation region (or slit) ANS between the first electrode 161 and the first electrode dummy pattern ANP is located above an air pocket AP.

In this case, the air pocket AP overlaps both a part of the first electrode 161 and a part of the first electrode dummy pattern ANP that are located at the same vertical level.

The first electrode 161 and the first electrode dummy pattern ANP may comprise a same material.

An insulating layer IN1 disposed on the substrate 100 may include a plurality of inorganic insulating layers such as a plurality of buffer layers, a gate insulating layer, and a plurality of interlayer insulating layers.

An insulating layer IN2 having the air pocket AP defined in a portion of the upper surface thereof may include one or more inorganic insulating layers, a color filter, and a planarization layer. The planarization layer may be located at the uppermost position.

In a non-emission portion NEM, a region for the air pocket AP may be defined by depressing a portion of the upper surface of the insulating layer IN2 including the planarization layer in a curved shape.

Alternatively, after a first electrode forming material is placed on the flat insulating layer IN2 including the planarization layer, the first electrode 161 may be provided at each sub-pixel, and the slit ANS between the first electrode 161 and the first electrode dummy pattern 265 or ANP may be provided in the non-emission portion NEM through a patterning process. Thereafter, a portion of the planarization layer may be isotropically etched through the slit ANS using an etchant having a different etch selectivity from that used for patterning the first electrode forming material. As a result, a region etched in a semicircular or arc shape into the planarization layer may be defined as the air pocket AP. Accordingly, the material of the planarization layer may be removed from the region of the air pocket AP, and the region may be filled with air.

The slit ANS between the first electrode 161 and the first electrode dummy pattern 265 or ANP is a very narrow gap. A material for forming the bank 170, which is placed on an edge of the first electrode 161 and on the first electrode dummy pattern 265 or ANP, does not flow into the slit ANS between the first electrode 161 and the first electrode dummy pattern 265 or ANP, so that the air pocket 265 or AP is maintained in a state of being filled with air. Accordingly, after the light emitting device 160 is provided, the curved interface between the lower surface of the air pocket AP and the planarization layer functions to refract and reflect the light emitted from the light emitting device 160 toward the emission portion due to the difference in refractive index between the air in the air pocket AP and the insulating layer IN2 including the planarization layer.

The light emitting display device of the present disclosure includes the air pocket AP below the bank 170, which is a structure defining the emission portion on the substrate, thereby adjusting the emission direction of the light that travels from the light emitting device in the radial direction. Accordingly, reflection or absorption of the light, generated from the intermediate layer 162 on the bank 170, within the substrate 100 may be reduced, and light extraction efficiency may be improved toward the emission portions REM, WEM, BEM, and GEM.

The light emitting display device of the present disclosure may reduce or prevent the light emitted in the radial direction from the light emitting device from traveling toward the lines (metal lines) within the substrate or toward the components of the transistor. In addition, the light extraction direction may be changed by the curved surface of the air pocket AP so as not to interfere with a metal or active layer, thereby increasing the light extraction rate through the substrate 100.

In the light emitting display device of the present disclosure, the light emitted in the radial direction from the sub-pixels RSP, WSP, BSP, and GSP may be directed back toward the substrate located in the emission portions REM, WEM, BEM, and GEM of the sub-pixels RSP, WSP, BSP, and GSP by the air pocket AP, thereby preventing or suppressing color mixing between adjacent sub-pixels and improving the electro-optical characteristics.

The light emitting display device of the present disclosure may readjust the emission direction of the light emitted from the light emitting device 160 through the air pocket AP and thus may increase the amount of light output through the substrate, thereby improving light extraction efficiency. As a result, power consumption may be reduced when achieving the same luminance. Therefore, the light emitting display device of the present disclosure may enhance emission efficiency and reduce power consumption without requiring additional materials for the configuration of the light emitting display device. This may contribute to long-term applicability, thereby enabling the implementation of Environmental/Social/Governance (ESG).

A light emitting display device according to one or more embodiments of the present disclosure may comprise a substrate comprising a plurality of sub-pixels, each comprising an emission portion and a non-emission portion, a pixel circuit on the substrate, a planarization layer covering the pixel circuit, a light emitting device comprising a first electrode on the planarization layer and provided at an entire area of the emission portion and at a part of the non-emission portion at each of the plurality of sub-pixels, a bank on the planarization layer and exposing the emission portion of the first electrode and an air pocket below the bank and disposed at an upper surface of the planarization layer.

In a light emitting display device according to one or more embodiments of the present disclosure, the air pocket may be disposed to overlap an edge of the bank and to surround the emission portion.

In a light emitting display device according to one or more embodiments of the present disclosure, the air pocket may be disposed to contain air between the planarization layer and the bank, and have a curved surface recessed at the upper surface of the planarization layer toward the substrate.

In a light emitting display device according to one or more embodiments of the present disclosure, the light emitting device may further comprise an intermediate layer on the first electrode and a second electrode on the intermediate layer, the intermediate layer and the second electrode on the emission portion of the first electrode and on a side surface and an upper surface of the bank. Light generated in the light emitting device may be reflected toward the planarization layer by the curved surface of the air pocket and is transmitted to the emission portion.

In a light emitting display device according to one or more embodiments of the present disclosure, the first electrode may be disposed between the air pocket and the bank. The bank may be in contact with an upper surface of the first electrode. Air may be contained between a lower surface of the first electrode and the upper surface of the planarization layer corresponding to a lower portion of the air pocket.

In a light emitting display device according to one or more embodiments of the present disclosure, the air pocket may have an arc shape below a lower surface of the bank in a cross-sectional view.

A light emitting display device according to one or more embodiments of the present disclosure may further comprise a first electrode dummy pattern to overlap the bank between adjacent sub-pixels among the plurality of sub-pixels, the first electrode dummy pattern being spaced apart from the first electrode at each of the adjacent sub-pixels.

In a light emitting display device according to one or more embodiments of the present disclosure, a part of the first electrode, a part of the first electrode dummy pattern, and a separation region between the first electrode and the first electrode dummy pattern may overlap the air pocket.

In a light emitting display device according to one or more embodiments of the present disclosure, the first electrode and the first electrode dummy pattern at each of the adjacent sub-pixels may be positioned at a same vertical level. The air pocket may be positioned at a lower vertical level than the first electrode.

In a light emitting display device according to one or more embodiments of the present disclosure, the air pocket may have a curved surface recessed from a lower surface of the first electrode and a lower surface of the first electrode dummy pattern toward the substrate on both sides of a separation region between the first electrode and the first electrode dummy pattern in a cross-sectional view. The upper surface of the planarization layer having an interface with the curved surface of the air pocket may be spaced vertically apart from the lower surface of the first electrode and the lower surface of the first electrode dummy pattern.

In a light emitting display device according to one or more embodiments of the present disclosure, the first electrode dummy pattern may be in a floating state.

In a light emitting display device according to one or more embodiments of the present disclosure, the air pocket may be disposed along sides of the emission portion, excluding one side of the emission portion adjacent to the pixel circuit.

In a light emitting display device according to one or more embodiments of the present disclosure, the air pocket may overlap at least one line or electrode included in the pixel circuit.

A light emitting display device according to one or more embodiments of the present disclosure may further comprise a color filter provided between the substrate and the planarization layer.

In a light emitting display device according to one or more embodiments of the present disclosure, the color filter may overlap the air pocket.

A light emitting display device according to one or more embodiments of the present disclosure may comprise a substrate comprising a red emission portion, a green emission portion, a blue emission portion, and a white emission portion spaced apart from each other, a pixel circuit on the substrate, a planarization layer covering the pixel circuit, a light emitting device comprising first electrodes respectively at the red emission portion, the green emission portion, the blue emission portion, and the white emission portion on the planarization layer, the first electrodes being spaced apart from each other, a bank on the planarization layer and exposing the red emission portion, the green emission portion, the blue emission portion, and the white emission portion of the first electrodes and an air pocket between the bank and the planarization layer, the air pocket overlapping the bank.

In a light emitting display device according to one or more embodiments of the present disclosure, the air pocket may surround each of the red emission portion, the green emission portion, the blue emission portion, and the white emission portion.

In a light emitting display device according to one or more embodiments of the present disclosure, each of the first electrodes may be in contact with a lower surface of the bank. Each of the first electrodes is in contact with a lower surface of the bank may overlap the air pocket. Air may be contained between a lower surface of each of the first electrodes and an upper surface of the planarization layer corresponding to a lower portion of the air pocket.

As is apparent from the above description, the light emitting display device according to one or more embodiments of the present disclosure includes an air pocket below a bank, which is a structure defining an emission portion on a substrate, thereby adjusting the emission direction of light. Accordingly, reflection or absorption of light, generated from an intermediate layer on the bank, within the substrate may be reduced, and light extraction efficiency may be improved.

The light emitting display device according to one or more embodiments of the present disclosure may reduce or prevent light emitted in the radial direction from a light emitting device from traveling toward lines within the substrate or toward components of a transistor. In addition, the light extraction direction may be changed by a curved surface of the air pocket so as not to interfere with a metal or active layer, thereby increasing the light extraction rate through the substrate.

In the light emitting display device according to one or more embodiments of the present disclosure, light emitted in the radial direction from sub-pixels may be directed back toward the substrate located in the sub-pixels by the air pocket, thereby preventing or suppressing color mixing between adjacent sub-pixels and improving electro-optical characteristics.

The light emitting display device according to one or more embodiments of the present disclosure may readjust the emission direction of the light emitted from the light emitting device through the air pocket and thus may increase the amount of light output through the substrate, thereby improving light extraction efficiency. As a result, power consumption may be reduced when achieving the same luminance. Therefore, the light emitting display device of the present disclosure may enhance emission efficiency and reduce power consumption without requiring additional materials for the configuration of the light emitting display device. This may contribute to long-term applicability, thereby enabling the implementation of Environmental/Social/Governance (ESG).

The effects achievable through the present disclosure are not limited to the above-mentioned effects, and other various effects may be directly or implicitly disclosed in the above detailed description of the present disclosure.

It will be apparent to those skilled in the art that various modifications and variations can be made in the present disclosure without departing from the spirit or scope of the present disclosure. Thus, it is intended that the present disclosure cover the modifications and variations of the present disclosure, including those that come within the scope of the appended claims and their equivalents.

What is claimed is:

1. A light emitting display device, comprising:
a substrate comprising a plurality of sub-pixels, each comprising an emission portion and a non-emission portion;
a pixel circuit on the substrate;
a planarization layer covering the pixel circuit;
a light emitting device comprising a first electrode on the planarization layer and provided at an entire area of the emission portion and at a part of the non-emission portion at each of the plurality of sub-pixels;
a bank on the planarization layer and exposing the emission portion of the first electrode; and
an air pocket below the bank and disposed at an upper surface of the planarization layer.

2. The light emitting display device according to claim 1, wherein the air pocket is disposed to overlap an edge of the bank and to surround the emission portion.

3. The light emitting display device according to claim 1, wherein the air pocket is disposed to contain air between the planarization layer and the bank, and has a curved surface recessed at the upper surface of the planarization layer toward the substrate.

4. The light emitting display device according to claim 3, wherein:
the light emitting device further comprises an intermediate layer on the first electrode and a second electrode on the intermediate layer, the intermediate layer and the second electrode on the emission portion of the first electrode and on a side surface and an upper surface of the bank, and
light generated in the light emitting device is reflected toward the planarization layer by the curved surface of the air pocket and is transmitted to the emission portion.

5. The light emitting display device according to claim 1, wherein:
the first electrode is disposed between the air pocket and the bank,
the bank is in contact with an upper surface of the first electrode, and
air is contained between a lower surface of the first electrode and the upper surface of the planarization layer corresponding to a lower portion of the air pocket.

6. The light emitting display device according to claim 1, wherein the air pocket has an arc shape below a lower surface of the bank in a cross-sectional view.

7. The light emitting display device according to claim 1, further comprising a first electrode dummy pattern to overlap the bank between adjacent sub-pixels among the plurality of sub-pixels, the first electrode dummy pattern being spaced apart from the first electrode at each of the adjacent sub-pixels.

8. The light emitting display device according to claim 7, wherein a part of the first electrode, a part of the first electrode dummy pattern, and a separation region between the first electrode and the first electrode dummy pattern overlap the air pocket.

9. The light emitting display device according to claim 7, wherein:
the first electrode and the first electrode dummy pattern at each of the adjacent sub-pixels are positioned at a same vertical level, and
the air pocket is positioned at a lower vertical level than the first electrode.

10. The light emitting display device according to claim 7, wherein:
the air pocket has a curved surface recessed from a lower surface of the first electrode and a lower surface of the first electrode dummy pattern toward the substrate on both sides of a separation region between the first electrode and the first electrode dummy pattern in a cross-sectional view, and
the upper surface of the planarization layer having an interface with the curved surface of the air pocket is spaced vertically apart from the lower surface of the first electrode and the lower surface of the first electrode dummy pattern.

11. The light emitting display device according to claim 7, wherein the first electrode dummy pattern is in a floating state.

12. The light emitting display device according to claim 1, wherein the air pocket is disposed along sides of the emission portion, excluding one side of the emission portion adjacent to the pixel circuit.

13. The light emitting display device according to claim 1, wherein the air pocket overlaps at least one line or electrode included in the pixel circuit.

14. The light emitting display device according to claim 1, further comprising a color filter provided between the substrate and the planarization layer.

15. The light emitting display device according to claim 14, wherein the color filter overlaps the air pocket.

16. A light emitting display device, comprising:
a substrate comprising a red emission portion, a green emission portion, a blue emission portion, and a white emission portion spaced apart from each other;
a pixel circuit on the substrate;
a planarization layer covering the pixel circuit;
a light emitting device comprising first electrodes respectively at the red emission portion, the green emission portion, the blue emission portion, and the white emission portion on the planarization layer, the first electrodes being spaced apart from each other;
a bank on the planarization layer and exposing the red emission portion, the green emission portion, the blue emission portion, and the white emission portion of the first electrodes; and
an air pocket between the bank and the planarization layer, the air pocket overlapping the bank.

17. The light emitting display device according to claim 16, wherein the air pocket surrounds each of the red emission portion, the green emission portion, the blue emission portion, and the white emission portion.

18. The light emitting display device according to claim 16, wherein:
each of the first electrodes is in contact with a lower surface of the bank,
each of the first electrodes is in contact with a lower surface of the bank overlaps the air pocket, and
air is contained between a lower surface of each of the first electrodes and an upper surface of the planarization layer corresponding to a lower portion of the air pocket.
